(19) United States
(12) Patent Application Publication
(10) Pub. No.: US 2026/0016501 A1
(43) Pub. Date: Jan. 15, 2026

(54) TEST INTERCONNECT WITH CONDUCTIVE PLANES AND COMPONENTS FOR POWER INTEGRITY AND THERMAL MANAGEMENT

(71) Applicant: Essai, Inc., San Jose, CA (US)

(72) Inventors: James HASTINGS, Chandler, AZ (US); Quaid Joher FURNITUREWALA, McKinney, TX (US); Rolf NEUWEILER, Magstadt (DE); Juergen SERRER, Stuttgart (DE); Joe XIAO, Chandler, AZ (US)

(21) Appl. No.: 18/882,549

(22) Filed: Sep. 11, 2024

Related U.S. Application Data
(60) Provisional application No. 63/670,044, filed on Jul. 11, 2024.

(51) Int. Cl. G01R 1/04

(52) U.S. Cl. CPC G01R 1/0466

(57) ABSTRACT

Test interconnect systems and methods are described. In one example, a test interconnect includes a housing structure that houses at least a portion of one or more compressible probes. The test interconnect also includes a plate that retains the one or more compressible probes relative to a load board, and a circuit board with one or more conductive planes that provide a conductive path for a supply voltage for a device under test. The circuit board is positioned on a side of the housing structure relative to a device under test that is opposite the load board side.

### CROSS-REFERENCE TO RELATED APPLICATIONS

This application claims the benefit of U.S. Provisional patent application titled, “TEST INTERCONNECT WITH CONDUCTIVE PLANES AND COMPONENTS FOR POWER INTEGRITY AND THERMAL MANAGEMENT,” filed on Jul. 11, 2024, and having Ser. No. 63/670,044. The subject matter of this related application is hereby incorporated herein by reference.

### BACKGROUND

### Field of the Various Embodiments

This application relates to systems and methods for reliable test tooling for packaged integrated circuits (IC) devices, and more specifically, to test interconnects with conductive planes and components for power integrity and thermal management.

### DESCRIPTION OF THE RELATED ART

Reliable test tooling for packaged integrated circuits (IC) devices often use testing sockets. Testing sockets can provide temporary connections to a device under test (DUT) and testing equipment. The testing equipment can perform one or more tests on the DUT while the testing socket acts as a temporary interconnect.

Testing sockets can include structures to hold the DUT in place for testing the DUT using a test circuit. Testing the DUT can include providing a positive supply voltage, sometimes referred to as a drain voltage “VDD” to power the DUT. Testing the DUT can also include providing a ground (or negative voltage), sometimes referred to as a source voltage “Vss.” to the DUT. However, one drawback of existing test systems (including the testing socket, load board, and tester) is that there is no provision to accurately detect VDD in locations near the DUT. Instead, existing technologies measure voltage from the load board side of the socket. This can limit the bandwidth of voltage measurements and cause changes in the voltage at the DUT due to the parasitic losses of a spring probe.

Another drawback of existing test sockets is that these test sockets are limited in their ability to improve “power integrity.” When power integrity suffers, excessive current fluctuations and voltage fluctuations can cause failures that invalidate testing as well as cause damage to the DUT, test socket, and load board. For example, localized current spikes can be caused by certain test vectors during new product development and testing, which can cause electrical damage to the DUT, socket, and load board. In addition, localized hot-spots can be caused by these current spikes that cause heat damage to the DUT, socket, and load board.

As the foregoing illustrates, what is needed in the art is testing interconnects and corresponding load board circuitry that can enable accurate detection of voltage near the DUT while improving power integrity by reducing current fluctuations.

### SUMMARY

One embodiment of the present disclosure sets forth a system that includes a housing structure that houses at least a portion of one or more compressible probes, a plate on a first surface of the housing structure, and a circuit board on a second surface of the housing structure opposite the first surface. The plate on the first surface of the housing structure retains the one or more compressible probes for connection to a load board. The circuit board includes one or more conductive planes that provide a conductive path for a supply voltage for a device under test (DUT), and the test interconnect is configured to interface with the DUT closer to the second surface of the housing structure than the first surface of the housing structure.

Another embodiment of the present disclosure sets forth a system that includes a load board comprising one or more load board contacts, a test interconnect assembly located between the load board and a device under test (DUT) interface of the test interconnect assembly, the test interconnect assembly comprising a housing structure that houses at least a portion of one or more compressible probes, a plate on a first surface of the housing structure closer to the load board than the DUT, wherein the plate retains the one or more compressible probes, and a circuit board on a second surface of the housing structure closer to the DUT interface than the load board, the circuit board comprising one or more conductive planes that provide a conductive path for a supply voltage

A further embodiment of the present disclose sets from a method that includes providing a test interconnect assembly comprising a device under test (DUT) interface, housing, using a housing structure of the test interconnect assembly, at least a portion of one or more compressible probes, attaching a plate of the test interconnect assembly on a first surface of the housing structure, wherein the plate retains the one or more compressible probes, attaching a circuit board on a second surface of the housing structure, the circuit board comprising one or more conductive planes that provide a conductive path for a supply voltage, and connecting a load board to the plate of the of the test interconnect assembly, the load board comprising load board contacts, wherein the test interconnect assembly is configured to connect to a DUT closer to the circuit board than the load board, the DUT comprising one or more DUT contacts

At least one technical advantage of the disclosed techniques relative to the prior art is that, with the disclosed techniques, a more accurate measurement of power supply voltage is obtained. Another technical advantage is that power supply integrity is increased. The improved power supply integrity reduces the likelihood of electrical damage, heat damage, and/or other damage to the DUT, the test socket, and the load board during testing. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, can be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is an exploded view of an example test system for power integrity and thermal management, according to various embodiments.

FIG. 2 is a cross-sectional view of a test system, according to various embodiments.

FIG. 3 is a cross-sectional view of another test system, according to various embodiments.

FIG. 4 is a cross-sectional view of another test system, according to various embodiments.

FIG. 5 is a detail view of a portion of a test interconnect assembly, according to various embodiments.

FIG. 6 is a flow diagram of method steps for power management using a test system, according to various embodiments.

FIG. 7 is a flow diagram of method steps for configuring a test system, according to various embodiments.

### DETAILED DESCRIPTION

In the following description, numerous specific details are set forth to provide a more thorough understanding of the various embodiments. However, it will be apparent to one of skilled in the art that the inventive concepts can be practiced without one or more of these specific details.

The described testing systems include interconnect assemblies that hold a DUT in place and perform a test of the DUT. An interconnect assembly provides circuit connections from a DUT to testing equipment such as a load board. Generally, the interconnect assembly can include a socket type structure or any structure to hold the DUT, and compressible probes that connect from the DUT to the load board. Testing the DUT can include providing one or more supply voltages (e.g., a positive voltage and/or a negative voltage) and a ground to the DUT.

During a test, the load board and other testing equipment applies a test pattern to the DUT through the interconnect assembly, and monitors voltages, currents, temperatures, and other parameters. However, one drawback of existing test systems is that there is no provision to accurately detect supply voltage in locations near the DUT. Unlike existing testing systems that measure voltage from the load board side, the test interconnect assemblies described herein enable DUT-side supply voltage measurements.

To this end, the described test interconnect assemblies include a circuit board on a DUT side of a housing (e.g., closer to the DUT than the load board). The circuit board includes one or more conductive planes that provide an additional conductive path for the one or more supply voltages for the DUT. Furthermore, the described test interconnect assemblies of some embodiments provide for DUT-side testing using Kelvin probes and other probes that connect to the DUT-side circuit board in various testing locations that can be inside or outside a device footprint. Accordingly, the described testing systems provide more accurate power supply measurements than prior technologies and also increase power supply integrity.

Another drawback of existing test sockets is their inability to improve power integrity, often resulting in voltage and current spikes as well as heat damage. Poor power integrity can cause damage to the DUT, test socket, and load board. Unlike existing testing systems that provide poor power integrity, the conductive planes of the DUT-side circuit board, and other components of the test interconnect assemblies, provide improved power integrity by providing additional conductive paths for source power (e.g., in addition to paths through the compressible probes). The additional conductive paths reduce current spikes and improve heat dissipation. Accordingly, the described testing systems reduce the likelihood of electrical damage, heat damage, and/or other damage to the DUT, the test socket, and the load board during testing. A more detailed description is provided through a discussion of the following figures.

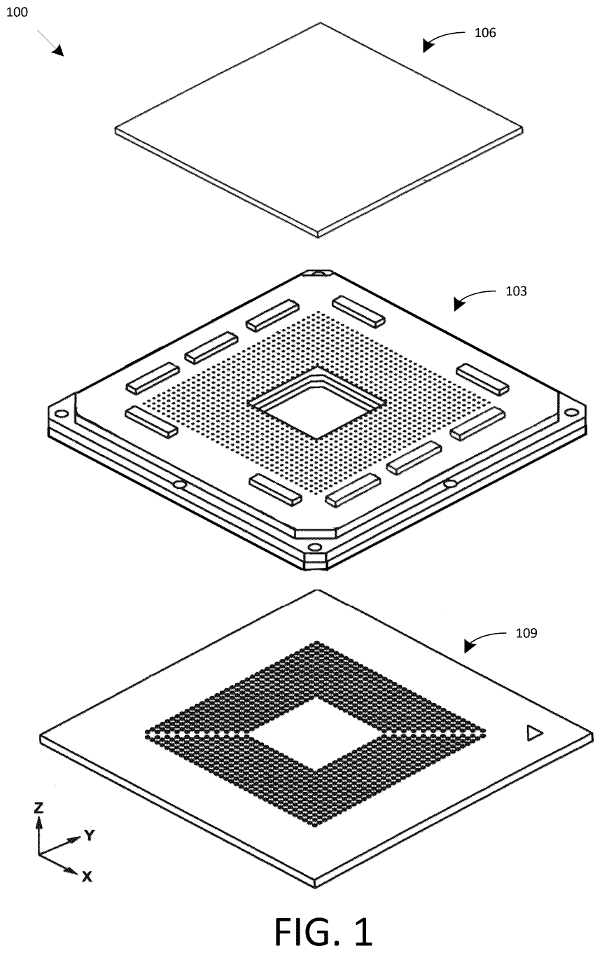

FIG. 1 is an exploded view of an example test system 100, according to various embodiments. Test system 100 includes, without limitation, a test interconnect assembly 103, a DUT 106, and a load board 109. The test interconnect assembly 103 includes a housing structure that houses compressible probes such as spring probes. The compressible probes include a subset of compressible probes that connect between the device under test 106 and the load board. The compressible probes also include a subset of compressible probes that connect between a DUT-side circuit board of the test interconnect assembly 103 and the load board 109. The DUT side of the test interconnect assembly 103 can refer to a side of the test interconnect assembly 103 that is closer to the DUT 106 as compared to the load board 109. The load board side of the test interconnect assembly 103 can refer to a side of the test interconnect assembly 103 that is closer to the load board 109 as compared to the DUT 106. A distal surface of the test interconnect assembly 103 can connect to the DUT 106, while a proximal surface of the test interconnect assembly 103 can connect to the load board 109. The DUT-side circuit board includes one or more conductive planes. The conductive planes include one or more VDD or supply voltage planes and one or more VSS or ground planes. The ground planes include one or more ground rails.

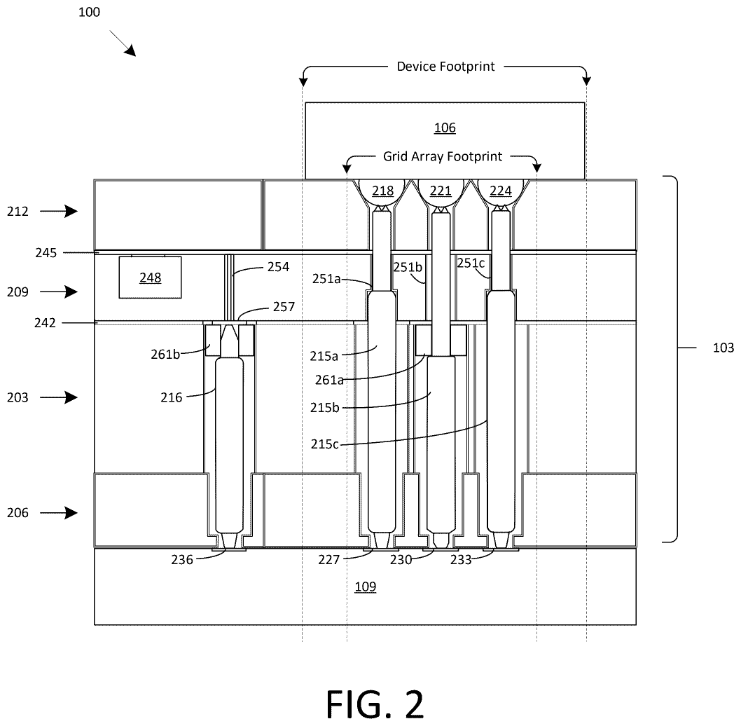

FIG. 2 is a cross-sectional view of a test system 100, according to various embodiments. Test system 100 includes, without limitation, a test interconnect assembly 103, a DUT 106, and a load board 109. The test interconnect assembly 103 includes, without limitation, a main housing structure 203, a cover plate 206, a circuit board 209, a stiffening plate 212, one or more compressible probes 215a, 215b, and 215c (collectively, “compressible probes 215”), and one or more measurement compressible probes 216. The test interconnect assembly 103 can include any number of compressible probes 215, and any number of measurement compressible probes 216. The DUT 106 includes, without limitation, a supply voltage contact 218, a signal contact 221, a ground contact 224, and other components. The load board 109 includes, without limitation, a supply voltage contact 227, a signal contact 230, a ground contact 233, a supply voltage measurement contact 236, and other components. The circuit board 209 includes, without limitation, one or more ground layers 242, one or more supply voltage layers 245, one or more capacitors 248, one or more hollow vias 251a, 251b, 251c (collectively, “hollow vias 251”), one or more vias 254, and one or more supply voltage measurement contacts 257. The test interconnect assembly 103 also includes one or more probe spacers 261a, 261b (collectively, “probe spacers 261”).

The DUT 106 includes a number of contacts arranged in a grid array. A grid array includes a pattern of any kind of contacts. For example, a grid array can include a ball grid array of solder ball contacts, a land grid array of contact pads, a pin grid array of pin contacts, and so on. The contacts of the DUT 106 can be referred to as DUT contacts. The grid array of the DUT 106 can be referred to as a DUT grid array. In FIG. 2, the DUT contacts are shown as solder ball contacts. And although only supply voltage contact 218, signal contact 221, and ground contact 224 are shown in FIG. 2, the DUT 106 can include any number of supply voltage contacts 218, any number of signal contacts 221, and any number of ground contacts 224. For example, some DUTs 106 can include one or more negative voltage contacts.

The load board 109 includes a number of contacts arranged in a grid array or contact array. The grid array of the load board 109 can be referred to as a load board grid array. In FIG. 2, the load board contacts are shown as contact pads. Although only one supply voltage contact 227, one signal contact 230, and one ground contact 233 are shown, the load board 109 can include any number of supply voltage contacts 227, any number of signal contacts 230, any number of ground contacts 233, and any number of supply voltage measurement contacts 236. Some load boards 109 include one or more negative voltage contacts (not shown).

The main housing structure 203 holds or houses the compressible probes 215. To this end, the test interconnect assembly 103 includes probe holes or cavities that extend through the main housing structure 203, the cover plate 206, the circuit board 209, and the stiffening plate 212. In FIG. 2, the probe holes and/or other components of the test interconnect assembly 103 hold the compressible probes 215 in an orientation that is orthogonal to the distal (e.g., closer to the DUT 106) and proximal (e.g., closer to the load board 109) surfaces of the main housing structure 203. However, in other examples, the probe holes can hold the compressible probes 215 at a predetermined angle. The angle of the compressible probes 215 can be uniform, or the angle can be different for each of the compressible probes 215. In some examples, the probe holes (and probe spacers) of the main housing structure 203 are sized and shaped to create a coaxial transmission path with a desired impedance to maximize signal transmission. In some examples, a predetermined or desired impedance can be 50 ohms (or any other desired impedance) to maximize signal transmission. The main housing structure 203 can be anodized, and the desired impedance can be achieved based on anodization parameters including, without limitation, use of a particular material, a particular thickness, and so on.

The main housing structure 203 can be constructed of a dielectric material such as plastic. In other examples, the main housing structure 203 can be constructed of a conductive material such as aluminum. In examples where the main housing structure 203 is constructed of a conductive material, the main housing structure 203 can be grounded by a connection to a compressible probe such as the compressible probe 215c. The main housing structure 203 can be anodized to prevent shorting other compressible probes 215. The compressible probe 215c connects between the ground contact 233 of the load board 109 and the ground contact 224 of the DUT 106. The compressible probe 215c can connect the main housing structure 203 to a ground net of an overall circuit that includes the DUT 106, the load board 109, and the test interconnect assembly 103. The compressible probe 215c can connect the main housing structure 203 to a ground net using a physical connection of the compressible probe 215c to a ground plane or ground layer 242 of the circuit board 209. The ground layer 242 of the circuit board 209 can make contact with the main housing structure 203. In other examples, a probe hole of the main housing structure 203 can be sized to make direct contact with the compressible probe 215c, or a conductive spacer that fits around the compressible probe 215c can connect the compressible probe 215c to the main housing structure 203. The grounding of the main housing structure 203 can create a coaxial structure in combination with the various compressible probes 215. The compressible probe 215b carries a signal between the load board 109 and the DUT 106. Each of the compressible probes 215a and 215b, and the measurement compressible probe 216 can be surrounded by an air gap and other dielectric materials. The dielectric materials can include the anodization of the main housing structure 203. The air gap and other dielectric materials can provide a desired impedance to maximize signal transmission. The air gap and other dielectric materials can be surrounded by a ground provided using the grounded main housing structure 203. The anodization of the main housing structure 203 provides at least a portion of the desired impedance based on anodization parameters.

Where the main housing structure 203 is constructed of a dielectric material, the probe holes can have a conductive sheath or coating that forms a coaxial structure. In some cases, the main housing structure 203 is constructed as a single integrated unit with the circuit board 209. The conductive sheath or coating can be grounded by making contact with a ground layer 242 of the circuit board 209. For example, the compressible probe 215b can carry a signal between the load board 109 and the DUT 106. Each of the compressible probes 215a and 215b, and the measurement compressible probe 216 can be surrounded by an air gap and other dielectric materials. The dielectric materials can include anodization over a conductive portion of the sheath or coating. The air gap and other dielectric materials can provide a desired impedance to maximize signal transmission. The air gap and other dielectric materials can be surrounded by a ground provided using the grounded conductive sheath or coating. The anodization of the sheath or coating provides at least a portion of the desired impedance based on anodization parameters.

The cover plate 206 interfaces with the load board 109. The cover plate 206 retains a proximal portion of the compressible probes 215. As a result, the cover plate 206 can be referred to as a compressible probe retention plate or a load board interface of the test interconnect assembly 103. The cover plate 206 can be constructed of a dielectric material such as plastic. In other examples, the cover plate 206 is constructed of a conductive material such as aluminum. In examples where the cover plate 206 is constructed of a conductive material, the cover plate 206 can be grounded by a connection to a compressible probe such as the compressible probe 215c. The proximal cover plate 206 can be anodized to prevent shorting other compressible probes 215. The compressible probe 215c connects the cover plate 206 to a ground net using a physical connection of the compressible probe 215c to a ground plane or ground layer 242 of the circuit board 209. A probe hole of the cover plate 206 can be sized to make direct contact with the compressible probe 215c, or a conductive spacer that fits around the compressible probe 215c can connect the compressible probe 215c to the cover plate 206. In examples where both the main housing structure 203 and the cover plate 206 are conductive, the main housing structure 203 can be grounded, and the cover plate 206 can be grounded by making contact with the main housing structure 203. The grounding of the cover plate 206 can create a coaxial structure in combination with the various compressible probes 215.

The cover plate 206 can provide a portion of the probe holes. The portion of the probe holes provided using the cover plate 206 can be sized and shaped to create a coaxial transmission path with a desired impedance to maximize signal transmission. In some examples, a predetermined or desired impedance can be 50 ohms (or another impedance) to maximize signal transmission. The cover plate 206 can be anodized, and a desired impedance can be achieved based on anodization parameters.

The circuit board 209 can include a printed circuit board or another type of circuit board. The circuit board 209 can be composed using fiberglass, ceramics, polyimide or another material. The circuit board 209 can have a composite construction that includes, without limitation, one or more dielectric material and one or more conductive layers or planes. Each conductive layer includes one or more conductive traces or areas. The circuit board 209 can include any number of ground layers 242. The circuit board 209 can include any number of supply voltage layers 245. The circuit board 209 can include any number of capacitors 248. The circuit board 209 can include any number of hollow vias 251.

In FIG. 2, the capacitors 248 are shown to be embedded within a surface of the circuit board 209. The material can be etched, cut out, or otherwise removed in the area where a capacitor 248 is to be embedded. The circuit board 209 can include cutouts or etched areas in an upper layer closer to the DUT 106 and cutouts or etched areas in a lower layer closer to the main housing structure 203. The cutouts or etched areas can accommodate the capacitors 248. However, in some cases a capacitor 248 can be attached to a surface of a circuit board 209. In that case, the stiffening plate 212 includes a cutout for the capacitor 248, or the stiffening plate 212 can be absent. The capacitors 248 can stabilize supply voltage levels supplied using the supply voltage layer 245 and traces. The capacitors 248 can also perform circuit functions in conjunction with the load board 109 and/or the DUT 106.

The circuit board 209 provides a portion of the probe holes of the test interconnect assembly 103. A probe hole can be provided using a hollow conductive via that is shaped to accommodate a portion of a compressible probe 215. Conductive vias through the circuit board 209 concentric to the grid array of the DUT 106 can be selectively connected to the conductive layers of the circuit board 209. However, in some examples, the via is not connected to any conductive layers. For example, in the shown configuration, the via for the compressible probe 215b is not connected to any conductive layer because there is no circuit board 209 layer corresponding to the signal that passes through the compressible probe 215b.

A portion of the probe hole for the compressible probe 215a is provided using a hollow via 251. The hollow via 251a can be plated or otherwise include a conductive material. The hollow via 251a provides a conductive connection to one or more supply voltage layers 245 of the circuit board 209. The connection to the supply voltage layers 245 of the circuit board 209 enables heat dissipation and additional supply voltage conductive paths in addition to the compressible probe 215a. Relative to previous technologies, this improves power integrity, reduces current fluctuations, and improves heat dissipation.

A portion of the probe hole for the compressible probe 215b is provided using a hollow via 251b of the circuit board 209. The hollow via 251b can be plated or otherwise include a conductive material that extends through the circuit board 209, or the hollow via 254 can refer to a hole drilled through the circuit board 209. A probe spacer 261a holds the compressible probe 215b concentric with the probe hole and the signal contact 221. The probe spacer 261a can include a shape, size, and dielectric material that is selected to provide a desired impedance that maximizes signal transmission through the compressible probe 215b.

A portion of the probe hole for the compressible probe 215c is provided using a hollow via 251c. The hollow via 251c can be plated or otherwise include a conductive material that extends through the circuit board 209. The hollow via 251c provides a conductive connection to one or more ground layers 242 of the circuit board 209. The connection to the ground layers 242 of the circuit board 209 enables heat dissipation and additional conductive paths in addition to the compressible probe 215c. Relative to previous technologies, this improves power integrity, reduces current fluctuations, and improves heat dissipation.

The circuit board 209 includes a supply voltage measurement contact 257. The compressible probe 216 connects to the supply voltage measurement contact 236 of the load board 109 and to the supply voltage measurement contact 257 of the circuit board 209. The circuit board 209 can include any number of supply voltage measurement contacts 257 to read the supply voltage in multiple locations. The supply voltage measurement contacts 257 enable accurate measurement of supply voltage as read from one or more locations nearer to the DUT 106 than the load board 109. A conductive via 254 connects the supply voltage measurement contact 257 to a supply voltage layer 245 of the circuit board 209. A probe spacer 261b holds the compressible probe 216 concentric with the probe hole and the via 254. The probe spacer 261b can include a shape, size, and/or dielectric material that is selected to provide a desired impedance.

The circuit board 209 retains a distal portion of the compressible probes 215 and measurement compressible probes 216. In some examples, the circuit board 209 can be too flexible to effectively hold the compressible probes 215. The stiffening plate 212 provides rigidity to hold the circuit board 209 solidly in place against the pressure exerted by the compressible robes 215. However, in other cases the circuit board 209 includes a rigid material and/or includes sufficient layers to prevent flexion based on the pressure exerted by the compressible robes 215. Where the circuit board 209 has sufficient strength and rigidity to prevent flexion based on the pressure exerted by the compressible robes 215, the stiffening plate 212 can be omitted. The circuit board 209 the stiffening plate 212, and/or a floating plate (not shown) can provide a DUT interface of the test interconnect assembly 103. The stiffening plate 212 can include a grid array alignment aid for the grid array of the DUT 106. For example, the stiffening plate 212 can include indents that can receive solder balls, pins, and other contacts of the DUT 106. The stiffening plate 212 can additionally or alternatively include one or more raised elements that make contact with a periphery of the DUT 106. In some examples, the stiffening plate 212 does not include a grid alignment aid, and a floating plate can provide a suspended grid alignment aid between the stiffening plate 212 and the DUT 106. The floating plate can include indents that can receive solder balls, pins, and other contacts to interface with the DUT 106. The floating plate can be suspended using springs or another compressible suspension device that can enable even contact between the contacts of the DUT 106 and the compressible probes 215. In examples where the stiffening plate 212 is omitted a floating plate can provide a compressible-suspended grid alignment aid between the circuit board 209 and the DUT 106.

A distal portion of each of the compressible probes 215 and measurement compressible probes 216 can be aligned concentric with the grid array of the DUT 106. A proximal portion of each of the compressible probes can be aligned concentric with the grid array of the load board 109. The compressible probe 215a connects the supply voltage contact 218 of the DUT 106 to the supply voltage contact 227 of the load board 109. The compressible probe 215a provides additional conductive paths and heat dissipation by connecting to the supply voltage layer 245 of the circuit board 209. This circuit connection can be referred to as a supply voltage net. The compressible probe 215b connects the signal contact 221 of the DUT 106 to the signal contact 230 of the load board 109. This circuit connection can be referred to as a signal net. The compressible probe 215c connects the ground contact 224 of the DUT 106 to the ground contact 233 of the load board 109. The compressible probe 215c provides additional conductive paths and heat dissipation by connecting to the ground layer 242 of the circuit board 209. This circuit connection can be referred to as a ground net.

The compressible probe 216 connects the supply voltage measurement contact 257 of the circuit board 209 to the supply voltage measurement contact 236 of the load board 109. The compressible probe 216 can include a high-bandwidth “Kelvin” type measurement probe. The Kelvin type of probe connection can effectively eliminate current path impedance and temperature effects, thereby enabling more accurate measurement of supply voltage as experienced near the DUT, as compared to measurements through the other compressible probes 215a, 215b, 215c. The supply voltage measurement contact 236 connects to the supply voltage layer 245 of the circuit board 209 using the via 254. Some of the conductive layers of the circuit board 209 extend outside the device footprint of the DUT 106. The compressible probe 216, the capacitor 248, the supply voltage measurement contact 257, and the via 254 can also be located outside the device footprint of the DUT 106. Locating these components outside the device footprint can help provide space and isolation for the Kelvin type of connection to a tester. The connection to the tester can include connecting to a portion of the load board 109 as shown, or connecting a cable to a testing device (not shown) separate from the load board 109. The Kelvin type of connection enables the tester to better measure and control the voltage close to the DUT 106, because the connection can bypass all or a portion of the temperature, resistance, capacitance, and inductance that can affect compressible probes 215a, 215b, 215c.

The test system 100 can perform a test of the DUT 106 once the test interconnect assembly 103 is deployed to provide interconnects between the DUT 106 and the load board 109. The test system 100 applies supply voltage(s) and performs test pattern(s) using the load board 109. The supply voltage(s) and test patterns can pass through all or a subset of the compressible probes 215a, 215b, 215c. Performing test patterns can include inputting analog and/or digital voltage signals to one or more signal nets, reading analog and/or digital voltage signals from the one or more signal nets, and so on. The test system 100 can take power measurements including, without limitation, current measurements, voltage measurements, and other measurements using the measurement compressible probe 216. In some examples, the test system 100 can take temperature measurements using the compressible probe 216 or a temperature sensor device (not shown). The test system 100 can perform a power management action based on the power measurements and temperature measurements. The power management action can include, without limitation, modifying a voltage output, modifying a current output, and disconnecting a power connection.

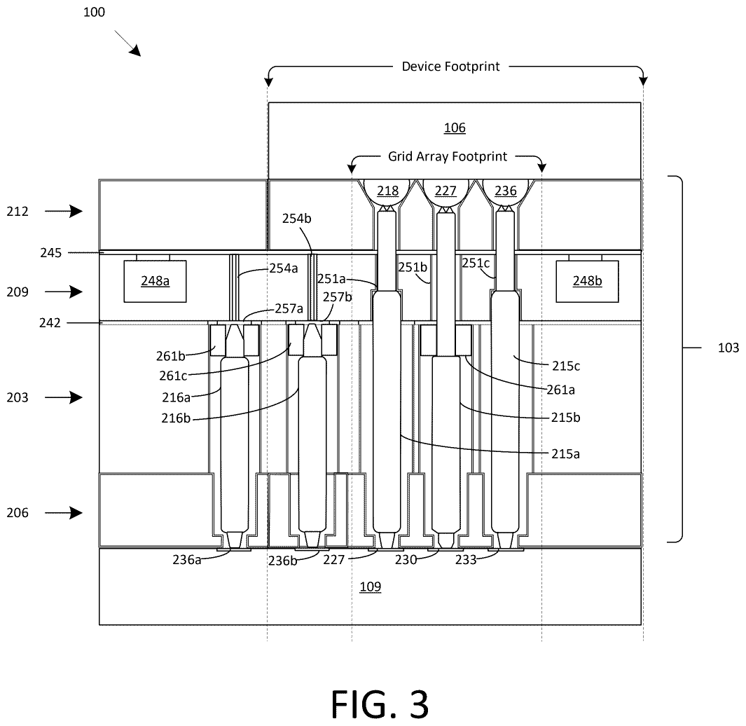

FIG. 3 is a cross-sectional view of another test system 100, according to various embodiments. Test system 100 shown in FIG. 3 includes, without limitation, a test interconnect assembly 103, a DUT 106, and a load board 109. The test interconnect assembly 103 includes, without limitation, a main housing structure 203, a cover plate 206, a circuit board 209, a stiffening plate 212, one or more compressible probes 215a, 215b, and 215c (collectively, “compressible probes 215”), and one or more measurement compressible probes 216a and 216b (collectively, “measurement compressible probes 216”). The test interconnect assembly 103 can include any number of compressible probes 215, and any number of measurement compressible probes 216. The DUT 106 includes, without limitation, a supply voltage contact 218, a signal contact 221, a ground contact 224, and other components. The load board 109 includes, without limitation, a supply voltage contact 227, a signal contact 230, a ground contact 233, one or more supply voltage measurement contacts 236a and 236b (collectively, “supply voltage measurement contacts 236”), and other components. The circuit board 209 includes, without limitation, one or more ground layers 242, one or more supply voltage layers 245, one or more capacitors 248, one or more hollow vias 251a, 251b, and 251c (collectively, “hollow vias 251”), one or more vias 254a and 254b (collectively vias 254), and one or more supply voltage measurement contacts 257a and 257b (collectively, “supply voltage measurement contacts 257”). The test interconnect assembly 103 can also include one or more probe spacers 261a, 261b, 261c (collectively, “probe spacers 261”).

The DUT 106 includes a number of contacts arranged in a grid array. The DUT contacts are shown as solder ball contacts. The DUT contacts include, without limitation, a supply voltage contact 218, a signal contact 221, and a ground contact 224. And although only three contacts are shown, the DUT 106 can include any number of supply voltage contacts 218, any number of signal contacts 221, and any number of ground contacts 224. Some DUTs 106 can include one or more negative voltage contacts.

The load board 109 includes a number of contacts arranged in a grid array or contact array. The load board contacts are shown as contact pads. The load board contacts include, without limitation, a supply voltage contact 227, a signal contact 230, a ground contact 233, and a supply voltage measurement contact 236. The load board 109 can include any number of supply voltage contacts 227, any number of signal contacts 230, any number of ground contacts 233, and any number of supply voltage measurement contacts 236. Some load boards 109 include one or more negative voltage contacts (not shown).

The main housing structure 203 holds or houses the compressible probes 215. To this end, the test interconnect assembly 103 includes probe holes or cavities that extend through the main housing structure 203, the cover plate 206, the circuit board 209, and the stiffening plate 212. The probe holes and/or other components of the test interconnect assembly 103 can hold the compressible probes 215 in any desired orientation. In some examples, the probe holes (and probe spacers) of the main housing structure 203 are sized and shaped to create a coaxial transmission path with a desired impedance to maximize signal transmission. The main housing structure 203 can be anodized, and the desired impedance can be achieved based on anodization parameters.

The main housing structure 203 can be constructed of a dielectric material such as plastic. In other examples, the main housing structure 203 can be constructed of a conductive material such as aluminum. In examples where the main housing structure 203 is constructed of a conductive material, the main housing structure 203 can be grounded by a connection to a compressible probe such as the compressible probe 215c. The main housing structure 203 can be anodized to prevent shorting other compressible probes 215. The compressible probe 215c connects between the ground contact 233 of the load board 109 and the ground contact 224 of the DUT 106. The compressible probe 215c can connect the main housing structure 203 to a ground net of an overall circuit that includes the DUT 106, the load board 109, and the test interconnect assembly 103. The compressible probe 215c can connect the main housing structure 203 to a ground net using a physical connection of the compressible probe 215c to a ground plane or ground layer 242 of the circuit board 209. The ground layer 242 of the circuit board 209 can make contact with the main housing structure 203. In other examples, a probe hole of the main housing structure 203 can be sized to make direct contact with the compressible probe 215c, or a conductive spacer that fits around the compressible probe 215c can connect the compressible probe 215c to the main housing structure 203. The grounding of the main housing structure 203 can create a coaxial structure in combination with the various compressible probes 215. The compressible probe 215b carries a signal between the load board 109 and the DUT 106. Each of the compressible probes 215a and 215b, and the measurement compressible probe 216 can be surrounded by an air gap and other dielectric materials. The dielectric materials can include the anodization of the main housing structure 203. The air gap and other dielectric materials can provide a desired impedance to maximize signal transmission. The air gap and other dielectric materials can be surrounded by a ground provided using the grounded main housing structure 203. The anodization of the main housing structure 203 provides at least a portion of the desired impedance based on anodization parameters.

In examples where the main housing structure 203 is constructed of a dielectric material, the probe holes can have a conductive sheath or coating that forms a coaxial structure. In some cases, the main housing structure 203 is constructed as a single integrated unit with the circuit board 209. The conductive sheath or coating can be grounded by making contact with a ground layer 242 of the circuit board 209. For example, the compressible probe 215b can carry a signal between the load board 109 and the DUT 106. Each of the compressible probes 215a and 215b, and the measurement compressible probe 216 can be surrounded by an air gap and other dielectric materials. The dielectric materials can include anodization over a conductive portion of the sheath or coating. The air gap and other dielectric materials can provide a desired impedance to maximize signal transmission. The air gap and other dielectric materials can be surrounded by a ground provided using the grounded conductive sheath or coating. The anodization of the sheath or coating provides at least a portion of the desired impedance based on anodization parameters.

The cover plate 206 interfaces with the load board 109. The cover plate 206 retains a proximal portion of the compressible probes 215. As a result, the cover plate 206 can be referred to as a compressible probe retention plate or a load board interface of the test interconnect assembly 103. The cover plate 206 can be constructed of a dielectric material such as plastic. In other examples, the cover plate 206 is constructed of a conductive material such as aluminum. In examples where the cover plate 206 is constructed of a conductive material, the cover plate 206 can be grounded by a connection to a compressible probe such as the compressible probe 215c. The proximal cover plate 206 can be anodized to prevent shorting other compressible probes 215. The compressible probe 215c connects the cover plate 206 to a ground net using a physical connection of the compressible probe 215c to a ground plane or ground layer 242 of the circuit board 209. A probe hole of the cover plate 206 can be sized to make direct contact with the compressible probe 215c, or a conductive spacer that fits around the compressible probe 215c can connect the compressible probe 215c to the cover plate 206. In examples where both the main housing structure 203 and the cover plate 206 are conductive, the main housing structure 203 can be grounded, and the cover plate 206 can be grounded by making contact with the main housing structure 203. The grounding of the cover plate 206 can create a coaxial structure in combination with the various compressible probes 215.

The cover plate 206 can provide a portion of the probe holes. The portion of the probe holes provided using the cover plate 206 can be sized and shaped to create a coaxial transmission path with a desired impedance to maximize signal transmission. The cover plate 206 can be anodized, and a desired impedance can be achieved based on anodization parameters.

The circuit board 209 can include a printed circuit board or another type of circuit board. The circuit board 209 can be composed using fiberglass, ceramics, polyimide or another material. The circuit board 209 can have a composite construction that includes, without limitation, one or more dielectric material and one or more conductive layers or planes. Each conductive layer includes one or more conductive traces or areas. The circuit board 209 can include any number of ground layers 242. The circuit board 209 can include any number of supply voltage layers 245. The circuit board 209 can include any number of capacitors 248. The circuit board 209 can include any number of hollow vias 251.

In the example of FIG. 3, the capacitors 248 include capacitor 248a and capacitor 248b. The capacitor 248a is located outside the device footprint. The capacitor 248b is located inside the device footprint and outside of the grid array footprint. Locating the capacitor 248b inside the device footprint increases the overall number (and density) of capacitors 248 of the circuit board 209. The increased number and density of capacitors 248 can increase power integrity inside the device footprint. The capacitors 248 are shown to be embedded within a surface of the circuit board 209. The material can be etched, cut out, or otherwise removed in the area where a capacitor 248 is to be embedded. The circuit board 209 can include cutouts or etched areas in an upper layer closer to the DUT 106 and cutouts or etched areas in a lower layer closer to the main housing structure 203. The cutouts or etched areas can accommodate the capacitors 248. However, in some cases a capacitor 248 can be attached to a surface of a circuit board 209. In that case, the stiffening plate 212 can include a cutout for the capacitor 248, or the stiffening plate 212 can be absent. The capacitors 248 can be used to stabilize supply voltage levels supplied using the supply voltage layer 245 and traces. The capacitors 248 can also be used to perform circuit functions in conjunction with the load board 109 and/or the DUT 106.

The circuit board 209 provides a portion of the probe holes of the test interconnect assembly 103. A probe hole can be provided using a hollow conductive via that is shaped to accommodate a portion of a compressible probe 215. Conductive vias through the circuit board 209 concentric to the grid array of the DUT 106 can be selectively connected to the conductive layers of the circuit board 209. However, in some examples, the via is not connected to any conductive layers. For example, in the shown configuration, the via for the compressible probe 215b is not connected to any conductive layer because there is no circuit board 209 layer corresponding to the signal that passes through the compressible probe 215b.

A portion of the probe hole for the compressible probe 215a is provided using a hollow via 251. The hollow via 251a can be plated or otherwise include a conductive material. The hollow via 251a provides a conductive connection to one or more supply voltage layers 245 of the circuit board 209. The connection to the supply voltage layers 245 of the circuit board 209 can enable heat dissipation and additional supply voltage conductive paths in addition to the compressible probe 215a. Relative to previous technologies, this can improve power integrity, reduce current fluctuations, and improve heat dissipation.

A portion of the probe hole for the compressible probe 215b is provided using a hollow via 251b of the circuit board 209. The hollow via 251b can be plated or otherwise include a conductive material that extends through the circuit board 209, or the hollow via 254 can refer to a hole drilled through the circuit board 209. A probe spacer 261a holds the compressible probe 215b concentric with the probe hole and the signal contact 221. The probe spacer 261a can include a shape, size, and dielectric material that is selected to provide a desired impedance that maximizes signal transmission through the compressible probe 215b.

A portion of the probe hole for the compressible probe 215c is provided using a hollow via 251c. The hollow via 251c can be plated or otherwise include a conductive material that extends through the circuit board 209. The hollow via 251c provides a conductive connection to one or more ground layers 242 of the circuit board 209. The connection to the ground layers 242 of the circuit board 209 can enable heat dissipation and additional conductive paths in addition to the compressible probe 215c. Relative to previous technologies, this can improve power integrity, reduce current fluctuations, and improve heat dissipation.

The circuit board 209 retains a distal portion of the compressible probes 215 and measurement compressible probes 216. In some examples, the circuit board 209 can be too flexible to effectively hold the compressible probes 215. The stiffening plate 212 provides rigidity to hold the circuit board 209 solidly in place against the pressure exerted by the compressible robes 215. However, in other cases the circuit board 209 includes a rigid material and/or includes sufficient layers to prevent flexion based on the pressure exerted by the compressible robes 215. Where the circuit board 209 can prevent flexion based on the pressure exerted by the compressible robes 215, the stiffening plate 212 can be omitted. The circuit board 209 the stiffening plate 212, and/or a floating plate (not shown) can provide a DUT interface of the test interconnect assembly 103. The stiffening plate 212 can include a grid array alignment aid for the grid array of the DUT 106. For example, the stiffening plate 212 can include indents that can receive solder balls, pins, and other contacts of the DUT 106. The stiffening plate 212 can additionally or alternatively include one or more raised elements that make contact with a periphery of the DUT 106. In some examples, the stiffening plate 212 does not include a grid alignment aid, and a floating plate can provide a suspended grid alignment aid between the stiffening plate 212 and the DUT 106. The floating plate can include indents that can receive solder balls, pins, and other contacts to interface with the DUT 106. The floating plate can be suspended using springs or another compressible suspension device that can enable even contact between the contacts of the DUT 106 and the compressible probes 215. In examples where the stiffening plate 212 is omitted a floating plate can provide a compressible-suspended grid alignment aid between the circuit board 209 and the DUT 106.

A distal portion of each of the compressible probes 215 and measurement compressible probes 216 can be aligned concentric with the grid array of the DUT 106. A proximal portion of each of the compressible probes can be aligned concentric with the grid array of the load board 109. The compressible probe 215a can connect the supply voltage contact 218 of the DUT 106 to the supply voltage contact 227 of the load board 109. The compressible probe 215a can provide additional conductive paths and heat dissipation by connecting to the supply voltage layer 245 of the circuit board 209. This circuit connection can be referred to as a supply voltage net. The compressible probe 215b can connect the signal contact 221 of the DUT 106 to the signal contact 230 of the load board 109. This circuit connection can be referred to as a signal net. The compressible probe 215c can connect the ground contact 224 of the DUT 106 to the ground contact 233 of the load board 109. The compressible probe 215c can provide additional conductive paths and heat dissipation by connecting to the ground layer 242 of the circuit board 209. This circuit connection can be referred to as a ground net.

The test system 100 can perform a test of the DUT 106 once the test interconnect assembly 103 is deployed to provide interconnects between the DUT 106 and the load board 109. The test system 100 applies supply voltage(s) and performs test pattern(s) using the load board 109. The supply voltage(s) and test patterns can pass through all or a subset of the compressible probes 215a, 215b, 215c. Performing test patterns can include inputting analog and/or digital voltage signals to one or more signal nets, reading analog and/or digital voltage signals from the one or more signal nets, and so on. The test system 100 can take power measurements including, without limitation, current measurements, voltage measurements, and other measurements using the compressible probe 216. In some examples, the test system 100 can take temperature measurements using the compressible probe 216 or a temperature sensor device (not shown). The test system 100 can perform a power management action based on the power measurements and temperature measurements. The power management action can include, without limitation, modifying a voltage output, modifying a current output, and disconnecting a power connection.

In the example of FIG. 3, the measurement compressible probes 216 can include measurement compressible probe 216a and measurement compressible probe 216b. The measurement compressible probe 216a can connect the supply voltage measurement contact 257a of the circuit board 209 to the supply voltage measurement contact 236a of the load board 109. The measurement compressible probe 216a can include a high-bandwidth “Kelvin” type measurement probe. The Kelvin type of probe connection can effectively eliminate current path impedance and temperature effects, thereby enabling more accurate measurement of supply voltage as experienced near the DUT, as compared to measurements through the other compressible probes 215a, 215b, 215c. The Kelvin type of connection enables the tester to better measure and control the voltage close to the DUT 106, because the Kelvin type measurement probe can bypass all or a portion of the temperature, resistance, capacitance, and inductance that can affect compressible probes 215a, 215b, 215c. The supply voltage measurement contact 236a can connect to the supply voltage layer 245 of the circuit board 209 using the via 254a. Some of the conductive layers of the circuit board 209 can extend outside the device footprint of the DUT 106. In some examples, measurement components such as the measurement compressible probe 216a, the supply voltage measurement contact 257a, and the via 254a are located outside the device footprint of the DUT 106. Locating these components outside the device footprint can help provide space and isolation for the Kelvin type of connection to a tester. A probe spacer 261b holds the measurement compressible probe 216a concentric with the probe hole and the via 254a. The probe spacer 261b can include a shape, size, and/or dielectric material that is selected to provide a desired impedance.

However, measurement components can also be located within the device footprint. For example, measurement components such as the compressible probe 216b, the supply voltage measurement contact 257b, and the via 254b are located inside the device footprint of the DUT 106 and outside of the grid array footprint. The measurement compressible probe 216b can connect the supply voltage measurement contact 257b of the circuit board 209 to the supply voltage measurement contact 236b of the load board 109. The measurement compressible probe 216b can include a high-bandwidth “Kelvin” type measurement probe. The supply voltage measurement contact 236b can connect to the supply voltage layer 245 of the circuit board 209 using the via 254b. Some of the conductive layers of the circuit board 209 can extend outside the device footprint of the DUT 106. Locating these components outside the grid array footprint can help provide space and isolation for the Kelvin type of connection to a tester, even with dense grid arrays. Locating the measurement compressible probe 216b inside the device footprint enables closer measurement of supply voltage and/or current closer to the current paths to the grid array of the DUT 106. A probe spacer 261c holds the measurement compressible probe 216b concentric with the probe hole and the via 254b. The probe spacer 261c can include a shape, size, and/or dielectric material that is selected to provide a desired impedance.

The test system 100 can perform a test of the DUT 106 once the test interconnect assembly 103 is deployed to provide interconnects between the DUT 106 and the load board 109. The test system 100 applies supply voltage(s) and performs test pattern(s) using the load board 109. The supply voltage(s) and test patterns can pass through all or a subset of the compressible probes 215a, 215b, 215c. Performing test patterns can include inputting analog and/or digital voltage signals to one or more signal nets, reading analog and/or digital voltage signals from the one or more signal nets, and so on. The test system 100 can take power measurements including, without limitation, current measurements, voltage measurements, and other measurements using the measurement compressible probe 216. In some examples, the test system 100 can take temperature measurements using the compressible probe 216 or a temperature sensor device (not shown). The test system 100 can perform a power management action based on the power measurements and temperature measurements. The power management action can include, without limitation, modifying a voltage output, modifying a current output, and disconnecting a power connection.

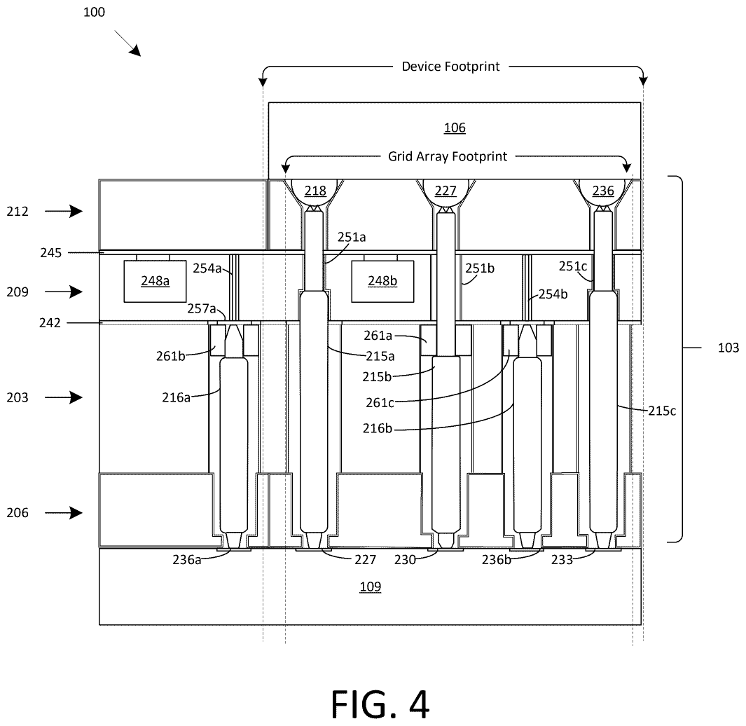

FIG. 4 is a cross-sectional view of another test system 100, according to various embodiments. Test system 100 shown in FIG. 4 includes, without limitation, a test interconnect assembly 103, a DUT 106, and a load board 109. The test interconnect assembly 103 includes, without limitation, a main housing structure 203, a cover plate 206, a circuit board 209, a stiffening plate 212, one or more compressible probes 215a, 215b, and 215c (collectively, “compressible probes 215”), and one or more measurement compressible probes 216a and 216b (collectively, “measurement compressible probes 216”). The test interconnect assembly 103 can include any number of compressible probes 215, and any number of measurement compressible probes 216. The DUT 106 includes, without limitation, a supply voltage contact 218, a signal contact 221, a ground contact 224, and other components. The load board 109 includes, without limitation, a supply voltage contact 227, a signal contact 230, a ground contact 233, one or more supply voltage measurement contacts 236a and 236b (collectively, “supply voltage measurement contacts 236”), and other components. The circuit board 209 includes, without limitation, one or more ground layers 242, one or more supply voltage layers 245, one or more capacitors 248, one or more hollow vias 251a, 251b, and 251c (collectively, “hollow vias 251”), one or more vias 254a and 254b (collectively vias 254), and one or more supply voltage measurement contacts 257a and 257b (collectively, “supply voltage measurement contacts 257”). The test interconnect assembly 103 can also include one or more probe spacers 261a, 261b, 261c (collectively, “probe spacers 261”).

The DUT 106 includes a number of contacts arranged in a grid array. A grid array includes a pattern of any kind of contacts. For example, a grid array can include a ball grid array of solder ball contacts, a land grid array of contact pads, a pin grid array of pin contacts, and so on. The contacts of the DUT 106 can be referred to as DUT contacts. The grid array of the DUT 106 can be referred to as a DUT grid array. The DUT contacts are shown as solder ball contacts. The DUT contacts include, without limitation, a supply voltage contact 218, a signal contact 221, and a ground contact 224. And although only three contacts are shown, the DUT 106 can include any number of supply voltage contacts 218, any number of signal contacts 221, and any number of ground contacts 224. Some DUTs 106 can include one or more negative voltage contacts.

The load board 109 includes a number of contacts arranged in a grid array or contact array. The grid array of the load board 109 can be referred to as a load board grid array. The load board contacts are shown as contact pads. The load board contacts include, without limitation, a supply voltage contact 227, a signal contact 230, a ground contact 233, and a supply voltage measurement contact 236. The load board 109 can include any number of supply voltage contacts 227, any number of signal contacts 230, any number of ground contacts 233, and any number of supply voltage measurement contacts 236. Some load boards 109 include one or more negative voltage contacts (not shown).

The main housing structure 203 holds or houses the compressible probes 215. To this end, the test interconnect assembly 103 includes probe holes or cavities that extend through the main housing structure 203, the cover plate 206, the circuit board 209, and the stiffening plate 212. The probe holes and/or other components of the test interconnect assembly 103 can hold the compressible probes 215 in any desired orientation. In some examples, the probe holes (and probe spacers) of the main housing structure 203 are sized and shaped to create a coaxial transmission path with a desired impedance to maximize signal transmission. The main housing structure 203 can be anodized, and the desired impedance can be achieved based on anodization parameters.

The main housing structure 203 can be constructed of a dielectric material. In other examples, the main housing structure 203 can be constructed of a conductive material. In examples where the main housing structure 203 is constructed of a conductive material, the main housing structure 203 can be grounded by a connection to a compressible probe such as the compressible probe 215c. The main housing structure 203 can be anodized to prevent shorting other compressible probes 215. The compressible probe 215c connects between the ground contact 233 of the load board 109 and the ground contact 224 of the DUT 106. The compressible probe 215c can connect the main housing structure 203 to a ground net of an overall circuit that includes the DUT 106, the load board 109, and the test interconnect assembly 103. The compressible probe 215c can connect the main housing structure 203 to a ground net using a physical connection of the compressible probe 215c to a ground plane or ground layer 242 of the circuit board 209. The ground layer 242 of the circuit board 209 can make contact with the main housing structure 203. In other examples, a probe hole of the main housing structure 203 can be sized to make direct contact with the compressible probe 215c, or a conductive spacer that fits around the compressible probe 215c can connect the compressible probe 215c to the main housing structure 203. The grounding of the main housing structure 203 can create a coaxial structure in combination with the various compressible probes 215. The compressible probe 215b carries a signal between the load board 109 and the DUT 106. Each of the compressible probes 215a and 215b, and the measurement compressible probe 216 can be surrounded by an air gap and other dielectric materials. The dielectric materials can include the anodization of the main housing structure 203. The air gap and other dielectric materials can provide a desired impedance to maximize signal transmission. The air gap and other dielectric materials can be surrounded by a ground provided using the grounded main housing structure 203. The anodization of the main housing structure 203 provides at least a portion of the desired impedance based on anodization parameters.

In examples where the main housing structure 203 is constructed of a dielectric material, the probe holes can have a conductive sheath or coating that forms a coaxial structure. In some cases, the main housing structure 203 main housing structure 203 is constructed as a single integrated unit with the circuit board 209. The conductive sheath or coating can be grounded by making contact with a ground layer 242 of the circuit board 209. For example, the compressible probe 215b can carry a signal between the load board 109 and the DUT 106. Each of the compressible probes 215a and 215b, and the measurement compressible probe 216 can be surrounded by an air gap and other dielectric materials. The dielectric materials can include anodization over a conductive portion of the sheath or coating. The air gap and other dielectric materials can provide a desired impedance to maximize signal transmission. The air gap and other dielectric materials can be surrounded by a ground provided using the grounded conductive sheath or coating. The anodization of the sheath or coating provides at least a portion of the desired impedance based on anodization parameters.

The cover plate 206 interfaces with the load board 109. The cover plate 206 retains a proximal portion of the compressible probes 215. As a result, the cover plate 206 can be referred to as a compressible probe retention plate or a load board interface of the test interconnect assembly 103. The cover plate 206 can be constructed of a dielectric material. In other examples, the cover plate 206 is constructed of a conductive material. In examples where the cover plate 206 is constructed of a conductive material, the cover plate 206 can be grounded by a connection to a compressible probe such as the compressible probe 215c. The proximal cover plate 206 can be anodized to prevent shorting other compressible probes 215. The compressible probe 215c connects the cover plate 206 to a ground net using a physical connection of the compressible probe 215c to a ground plane or ground layer 242 of the circuit board 209. A probe hole of the cover plate 206 can be sized to make direct contact with the compressible probe 215c, or a conductive spacer that fits around the compressible probe 215c can connect the compressible probe 215c to the cover plate 206. In examples where both the main housing structure 203 and the cover plate 206 are conductive, the main housing structure 203 can be grounded, and the cover plate 206 can be grounded by making contact with the main housing structure 203. The grounding of the cover plate 206 can create a coaxial structure in combination with the various compressible probes 215.

The cover plate 206 can provide a portion of the probe holes. The portion of the probe holes provided using the cover plate 206 can be sized and shaped to create a coaxial transmission path with a desired impedance to maximize signal transmission. The cover plate 206 can be anodized, and a desired impedance can be achieved based on anodization parameters.

The circuit board 209 can include a printed circuit board or another type of circuit board. The circuit board 209 can be composed using fiberglass, ceramics, polyimide or another material. The circuit board 209 can have a composite construction that includes, without limitation, one or more dielectric material and one or more conductive layers or planes. Each conductive layer includes one or more conductive traces or areas. The circuit board 209 can include any number of ground layers 242. The circuit board 209 can include any number of supply voltage layers 245. The circuit board 209 can include any number of capacitors 248. The circuit board 209 can include any number of hollow vias 251.

In the example of FIG. 4, the capacitors 248 include capacitor 248a and capacitor 248b. The capacitor 248a is located outside the device footprint. The capacitor 248b is located inside of the grid array footprint. Locating the capacitor 248b inside the grid array footprint increases the overall number (and density) of capacitors 248 of the circuit board 209. The increased number and density of capacitors 248 can increase power integrity in the area inside the grid array footprint. The capacitors 248 are shown to be embedded within a surface of the circuit board 209. The material can be etched, cut out, or otherwise removed in the area where a capacitor 248 is to be embedded. The circuit board 209 can include cutouts or etched areas in an upper layer closer to the DUT 106 and cutouts or etched areas in a lower layer closer to the main housing structure 203. The cutouts or etched areas can accommodate the capacitors 248. However, in some cases a capacitor 248 can be attached to a surface of a circuit board 209. In that case, the stiffening plate 212 can include a cutout for the capacitor 248, or the stiffening plate 212 can be absent. The capacitors 248 can be used to stabilize supply voltage levels supplied using the supply voltage layer 245 and traces. The capacitors 248 can also be used to perform circuit functions in conjunction with the load board 109 and/or the DUT 106.

The circuit board 209 provides a portion of the probe holes of the test interconnect assembly 103. A probe hole can be provided using a hollow conductive via that is shaped to accommodate a portion of a compressible probe 215. Conductive vias through the circuit board 209 concentric to the grid array of the DUT 106 can be selectively connected to the conductive layers of the circuit board 209. However, in some examples, the via is not connected to any conductive layers. For example, in the shown configuration, the via for the compressible probe 215b is not connected to any conductive layer because there is no circuit board 209 layer corresponding to the signal that passes through the compressible probe 215b.

A portion of the probe hole for the compressible probe 215a is provided using a hollow via 251. The hollow via 251a can be plated or otherwise include a conductive material. The hollow via 251a provides a conductive connection to one or more supply voltage layers 245 of the circuit board 209. The connection to the supply voltage layers 245 of the circuit board 209 can enable heat dissipation and additional supply voltage conductive paths in addition to the compressible probe 215a. Relative to previous technologies, this can improve power integrity, reduce current fluctuations, and improve heat dissipation.

A portion of the probe hole for the compressible probe 215b is provided using a hollow via 251b of the circuit board 209. The hollow via 251b can be plated or otherwise include a conductive material that extends through the circuit board 209, or the hollow via 254 can refer to a hole drilled through the circuit board 209. A probe spacer 261a holds the compressible probe 215b concentric with the probe hole and the signal contact 221. The probe spacer 261a can connect to one or more ground layers 242 of the circuit board 209. The probe spacer 261a can include a shape, size, and material that is selected to provide a desired impedance that maximizes signal transmission through the compressible probe 215b.

A portion of the probe hole for the compressible probe 215c is provided using a hollow via 251c. The hollow via 251c can be plated or otherwise include a conductive material that extends through the circuit board 209. The hollow via 251c provides a conductive connection to one or more ground layers 242 of the circuit board 209. The connection to the ground layers 242 of the circuit board 209 can enable heat dissipation and additional conductive paths in addition to the compressible probe 215c. Relative to previous technologies, this can improve power integrity, reduce current fluctuations, and improve heat dissipation.

The circuit board 209 retains a distal portion of the compressible probes 215 and measurement compressible probes 216. In some examples, the circuit board 209 can be too flexible to effectively hold the compressible probes 215. The stiffening plate 212 provides rigidity to hold the circuit board 209 solidly in place against the pressure exerted by the compressible robes 215. However, in other cases the circuit board 209 includes a rigid material and/or includes sufficient layers to prevent flexion based on the pressure exerted by the compressible robes 215. Where the circuit board 209 can prevent flexion based on the pressure exerted by the compressible robes 215, the stiffening plate 212 can be omitted. The circuit board 209 the stiffening plate 212, and/or a floating plate (not shown) can provide a DUT interface of the test interconnect assembly 103. The stiffening plate 212 can include a grid array alignment aid for the grid array of the DUT 106. For example, the stiffening plate 212 can include indents that can receive solder balls, pins, and other contacts of the DUT 106. The stiffening plate 212 can additionally or alternatively include one or more raised elements that make contact with a periphery of the DUT 106. In some examples, the stiffening plate 212 does not include a grid alignment aid, and a floating plate can provide a suspended grid alignment aid between the stiffening plate 212 and the DUT 106. The floating plate can include indents that can receive solder balls, pins, and other contacts to interface with the DUT 106. The floating plate can be suspended using springs or another compressible suspension device that can enable even contact between the contacts of the DUT 106 and the compressible probes 215. In examples where the stiffening plate 212 is omitted a floating plate can provide a compressible-suspended grid alignment aid between the circuit board 209 and the DUT 106.

A distal portion of each of the compressible probes 215 and measurement compressible probes 216 can be aligned concentric with the grid array of the DUT 106. A proximal portion of each of the compressible probes can be aligned concentric with the grid array of the load board 109. The compressible probe 215a can connect the supply voltage contact 218 of the DUT 106 to the supply voltage contact 227 of the load board 109. The compressible probe 215a can provide additional conductive paths and heat dissipation by connecting to the supply voltage layer 245 of the circuit board 209. This circuit connection can be referred to as a supply voltage net. The compressible probe 215b can connect the signal contact 221 of the DUT 106 to the signal contact 230 of the load board 109. This circuit connection can be referred to as a signal net. The compressible probe 215c can connect the ground contact 224 of the DUT 106 to the ground contact 233 of the load board 109. The compressible probe 215c can provide additional conductive paths and heat dissipation by connecting to the ground layer 242 of the circuit board 209. This circuit connection can be referred to as a ground net.

The test system 100 can perform a test of the DUT 106 once the test interconnect assembly 103 is deployed to provide interconnects between the DUT 106 and the load board 109. The test system 100 applies supply voltage(s) and performs test pattern(s) using the load board 109. The supply voltage(s) and test patterns can pass through all or a subset of the compressible probes 215a, 215b, 215c. Performing test patterns can include inputting analog and/or digital voltage signals to one or more signal nets, reading analog and/or digital voltage signals from the one or more signal nets, and so on. The test system 100 can take power measurements including, without limitation, current measurements, voltage measurements, and other measurements using the compressible probe 216. In some examples, the test system 100 can take temperature measurements using the compressible probe 216 or a temperature sensor device (not shown). The test system 100 can perform a power management action based on the power measurements and temperature measurements. The power management action can include, without limitation, modifying a voltage output, modifying a current output, and disconnecting a power connection.

In the example of FIG. 4, the measurement compressible probes 216 can include measurement compressible probe 216a and measurement compressible probe 216b. The measurement compressible probe 216a can connect the supply voltage measurement contact 257a of the circuit board 209 to the supply voltage measurement contact 236a of the load board 109. The measurement compressible probe 216a can include a high-bandwidth “Kelvin” type measurement probe. The Kelvin type of connection enables the tester to better measure and control the voltage close to the DUT 106, because the Kelvin type measurement probe can bypass all or a portion of the temperature, resistance, capacitance, and inductance that can affect compressible probes 215a, 215b, 215c. The supply voltage measurement contact 236a can connect to the supply voltage layer 245 of the circuit board 209 using the via 254a. Some of the conductive layers of the circuit board 209 can extend outside the device footprint of the DUT 106. In some examples, measurement components such as the measurement compressible probe 216a, the supply voltage measurement contact 257a, and the via 254a are located outside the device footprint of the DUT 106. Locating these components outside the device footprint can help provide space and isolation for the Kelvin type of connection to a tester. A probe spacer 261a holds the measurement compressible probe 216a concentric with the probe hole and the via 254a. The probe spacer 261b can include a shape, size, and/or dielectric material that is selected to provide a desired impedance.

However, measurement components can also be located within the device footprint and the grid array footprint. For example, measurement components such as the compressible probe 216b, the supply voltage measurement contact 257b, and the via 254b are located inside the device footprint of the DUT 106 and outside of the grid array footprint. The measurement compressible probe 216b can connect the supply voltage measurement contact 257b of the circuit board 209 to the supply voltage measurement contact 236b of the load board 109. The measurement compressible probe 216b can include a high-bandwidth “Kelvin” type measurement probe. The supply voltage measurement contact 236b can connect to the supply voltage layer 245 of the circuit board 209 using the via 254b. Some of the conductive layers of the circuit board 209 can extend outside the device footprint of the DUT 106. Locating the measurement compressible probe 216b inside the grid array footprint enables closer measurement of supply voltage and/or current closer to the current paths to the grid array of the DUT 106. A probe spacer 261c holds the measurement compressible probe 216b concentric with the probe hole and the via 254b. The probe spacer 261c can include a shape, size, and/or dielectric material that is selected to provide a desired impedance.

The test system 100 can perform a test of the DUT 106 once the test interconnect assembly 103 is deployed to provide interconnects between the DUT 106 and the load board 109. The test system 100 applies supply voltage(s) and performs test pattern(s) using the load board 109. The supply voltage(s) and test patterns can pass through all or a subset of the compressible probes 215a, 215b, 215c. Performing test patterns can include inputting analog and/or digital voltage signals to one or more signal nets, reading analog and/or digital voltage signals from the one or more signal nets, and so on. The test system 100 can take power measurements including, without limitation, current measurements, voltage measurements, and other measurements using the measurement compressible probe 216. In some examples, the test system 100 can take temperature measurements using the compressible probe 216 or a temperature sensor device (not shown). The test system 100 can perform a power management action based on the power measurements and temperature measurements. The power management action can include, without limitation, modifying a voltage output, modifying a current output, and disconnecting a power connection.

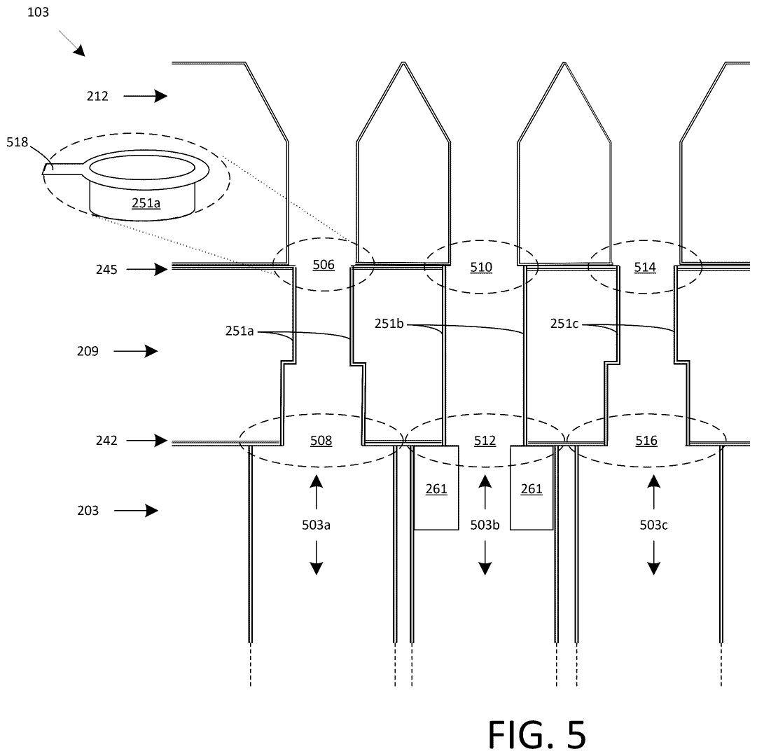

FIG. 5 is a detail view of a portion of a test interconnect assembly 103, according to various embodiments. The test interconnect assembly 103 includes, without limitation, a main housing structure 203, a circuit board 209, a stiffening plate 212, one or more compressible probe holes 503 to contain one or more compressible probes 215 (not shown) and/or measurement compressible probes 216 (not shown), one or more probe spacers 261, via connection areas 506, 508, 510, 512, 514, 516, and other components discussed with respect to other figures. The circuit board 209 includes, without limitation, one or more ground layers 242, one or more supply voltage layers 245 with one or more traces or conductive paths 518, one or more hollow vias 251a, 251b, and 251c (collectively, “hollow vias 251”), and other components discussed with respect to other figures.

The test interconnect assembly 103 includes probe holes 503a, 503b, and 503c that hold the compressible probes (not shown) and/or measurement compressible probes 216 (not shown). The probe holes 503 extend through the main housing structure 203, the cover plate 206 (not shown), the circuit board 209, and the stiffening plate 212. The probe holes 503 and/or other components of the test interconnect assembly 103 can hold the compressible probes 215 in an orientation that is orthogonal to the distal (e.g., closer to the DUT 106) and proximal (e.g., closer to the load board 109) surfaces of the main housing structure 203. However, in other examples, the probe holes 503 can hold the compressible probes 215 at any predetermined angle. The angle of the probe holes 503 can be uniform, or the angle can be different for each of the probe holes 503.

The circuit board 209 can include a printed circuit board or another type of circuit board. The circuit board 209 can be composed using fiberglass, ceramics, polyimide or another material. The circuit board 209 can have a composite construction that includes, without limitation, one or more dielectric material and one or more conductive layers or planes. Each conductive layer includes one or more conductive traces or areas. The circuit board 209 can include any number of ground layers 242. The circuit board 209 can include any number of supply voltage layers 245.

The via connection area 506 can refer to the area of the circuit board 209 that encircles or surrounds the probe hole 503a in the supply voltage layer 245. A portion of the probe hole 503a is provided using a hollow via 251a. The hollow via 251a can be plated or otherwise include a conductive material. In this example, the hollow via 251a provides a connection to the supply voltage layer 245 of the circuit board 209. The supply voltage layer 245 can include, in the via connection area 506, one or more supply voltage traces and/or connections that connect to the hollow via 251a. The connection to the supply voltage layers 245 of the circuit board 209 can enable heat dissipation and additional supply voltage conductive paths. The hollow via 251a can be sized and shaped to receive and make contact with a corresponding compressible probe 215 (not shown) that connects to a supply voltage net. The zoomed in isometric view of the via connection area 506 shows a conductive path 518 that makes contact with and encircles the hollow via 251a. In other embodiments, multiple conductive paths 518, and/or a solid conductive plane of the ground layer 242 makes contact with the hollow via 251a and extends in all directions therefrom.

The via connection area 508 can refer to the area of the circuit board 209 that encircles or surrounds the probe hole 503a in the ground layer 242. In the via connection area 508, the ground layer 242 can include an open space or dielectric area around the probe hole 503a, so that the ground layer 242 does not short to the source-voltage-connected hollow via 251a. The material and/or size of the open space or dielectric area of the ground layer 242 in the via connection area 508 can be sized and shaped to provide a desired impedance to ground.

The via connection area 510 can refer to the area of the circuit board 209 that encircles or surrounds the probe hole 503b in the supply voltage layer 245. A portion of the probe hole 503a is provided using a hollow via 251b. The hollow via 251b can be plated or otherwise include a conductive material. In this example the hollow via 251b corresponds to a compressible probe 215 (not shown) that provides a signal path. The supply voltage layer 245 can include, in the via connection area 510, an open space or dielectric area around the probe hole 503b. As a result, the hollow via 251b does not connect to the supply voltage layer 245 of the circuit board 209.

The via connection area 512 can refer to the area of the circuit board 209 that encircles or surrounds the probe hole 503b in the ground layer 242. In order to provide a coaxial transmission path, the hollow via 251b can be grounded. To this end, the ground layer 242 in the via connection area 512 can include one or more traces and/or connections that connect to the hollow via 251b. The hollow via 251b can be sized to prevent contact with a corresponding compressible probe 215 (not shown) that connects to a signal net. To this end, the probe spacer 261 can hold the compressible probe 215 (not shown) away from the edges of hollow via 251b. The material, size, and shape of the probe spacer can provide a desired impedance to maximize signal transmission.

The via connection area 514 can refer to the area of the circuit board 209 that encircles or surrounds the probe hole 503c in the supply voltage layer 245. A portion of the probe hole 503c is provided using a hollow via 251c. The hollow via 251c can be plated or otherwise include a conductive material. In this example the hollow via 251c corresponds to a compressible probe 215 (not shown) that provides a ground connection. The supply voltage layer 245 can include, in the via connection area 514, an open space or dielectric area around the probe hole 503c. As a result, the hollow via 251c does not connect to the supply voltage layer 245 of the circuit board 209.

The via connection area 516 can refer to the area of the circuit board 209 that encircles or surrounds the probe hole 503b in the ground layer 242. In order to provide a ground connection, the hollow via 251b can be grounded. To this end, the ground layer 242 in the via connection area 516 can include one or more traces and/or connections that connect to the hollow via 251b. The hollow via 251c can be sized and shaped to receive and make contact with a corresponding compressible probe 215 (not shown) that connects to a ground net.

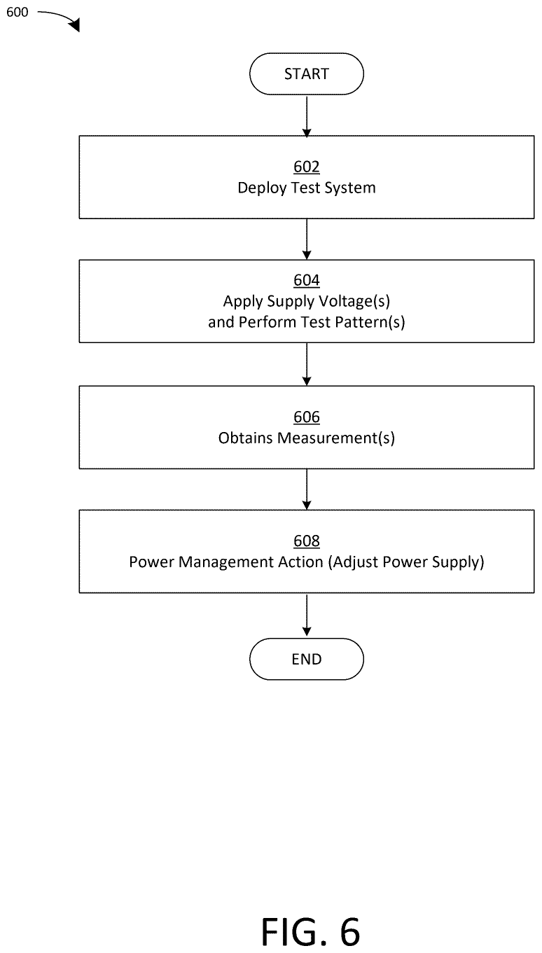

FIG. 6 is a flow diagram of method steps for power management using a test system, according to various embodiments. Although the method steps are described in conjunction with the systems of FIGS. 1-5, persons of ordinary skill in the art will understand that any system configured to perform the method steps, in any order, is within the scope of the invention.

As shown, a method 600 begins at step 602, where a test system 100 is deployed to provide interconnects between the DUT 106 and the load board 109. The test system 100 includes, without limitation, a test interconnect assembly 103, a DUT 106, and a load board 109. A first side of the test interconnect assembly 103 is connected to the load board 109. A second side of the test interconnect assembly 103 is connected to the DUT 106. The test interconnect assembly 103 includes a main housing structure 203, a cover plate 206, a circuit board 209, one or more compressible probes 215 and one or more measurement compressible probes 216. In some examples, the test interconnect assembly 103 includes a stiffening plate 212. Various configurations of the test interconnect assembly 103 are discussed with respect to FIGS. 1-5 and 7.

At step 604, the test system 100 applies supply voltage(s) and performs test pattern(s) using the load board 109. The load board 109 can include and/or be connected to a power supply device that provides supply voltages and test patterns. The load board 109 can include circuitry configured to apply positive and/or negative supply voltages and test patterns. The test patterns can include inputting analog and/or digital voltage signals to one or more signal nets, reading analog and/or digital voltage signals from the one or more signal nets, and so on.

At step 606, the test system 100 obtains measurements of various parameters of the test system 100. The test system 100 takes power measurements including, without limitation, current measurements, voltage measurements, and other measurements using the measurement compressible probes 216. The Kelvin-type measurement compressible probes 216 are connected to the DUT-side circuit board 209 distal from the load board 109, and provide DUT-side measurements. The test system 100 can also takes power measurements through the compressible probes 215. However, the measurements through the compressible probes 215 can cause current path impedance and temperature effects as compared to the Kelvin-type measurement compressible probes 216. As a result, the power measurements taken through the compressible probes 215 can be considered load-board-side measurements. In some examples, the test system 100 can take temperature measurements using the compressible probe 216 or a temperature sensor device.

At step 608, the test system 100 performs a power management action. The power management action can include, without limitation, modifying a voltage output, modifying a current output, and disconnecting a power connection. A power supply can be part of the load board 109, or can be separate from the load board 109. The test system 100 can include a control circuit, which can be part of the load board 109, or can be separate from the load board 109. The control circuit reads power measurements and temperature measurements taken using the measurement compressible probes 216 and/or the compressible probes 215. The control circuit identifies a power management action based on the power measurements and temperature measurements.

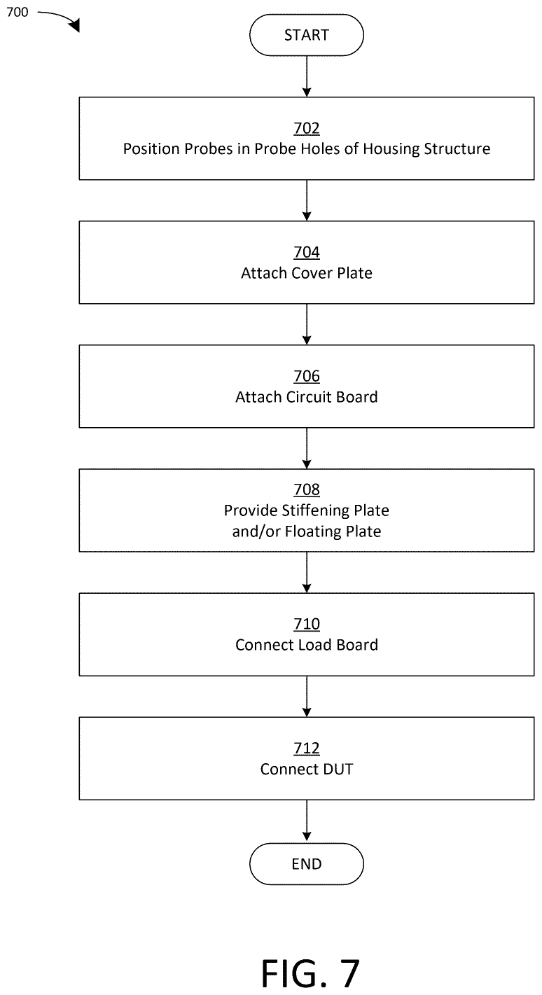

FIG. 7 is a flow diagram of method steps for configuring a test system, according to various embodiments. Although the method steps are described in conjunction with the systems of FIGS. 1-5, persons of ordinary skill in the art will understand that any system configured to perform the method steps, in any order, is within the scope of the invention.

As shown, a method 700 begins at step 702, where probes are positioned in probe holes 503 of a main housing structure 203. The main housing structure 203 can be constructed of a dielectric material and/or a conductive material. In examples where the main housing structure 203 is constructed of a conductive material, the main housing structure 203 can be grounded by a connection to a compressible probe 215 and/or a connection to circuit board 209. This grounding can enable a coaxial signal path for compressible probes 215 that carry signals and other voltages. The main housing structure 203 can be anodized to prevent shorting compressible probes 215 for signals and supply voltage.

The probe holes 503 can be at any angle relative to the DUT side and load board size of the main housing structure 203. The probes include compressible probes 215 for interconnections between a DUT 106 and a load board 109. The probes also include measurement compressible probes 216, which can include Kelvin-type probes. Positioning probes in probe holes 503 can include positioning probe spacers 261 in the probe holes 503 or onto probes prior to insertion of the probes into the probe holes 503.

At step 704, a cover plate 206 is attached to the main housing structure 203. The cover plate 206 is configured to interface with the load board 109. The cover plate 206 retains a proximal portion of the compressible probes 215, relative to the load board 109. The cover plate 206 can be constructed of a dielectric material and/or a conductive material. In examples where the cover plate 206 is constructed of a conductive material, the cover plate 206 can be grounded by a connection to a compressible probe 215 or a connection to the main housing structure 203. This grounding can enable a coaxial signal path for compressible probes 215 that carry signals and other voltages. The cover plate 206 can be anodized to prevent shorting compressible probes 215 for signals and supply voltage.

At step 706, the circuit board 209 is attached to the main housing structure 203 on a DUT-side relative to the load board 109. The circuit board 209 includes a printed circuit board or another type of circuit board 209. In some examples, the circuit board 209 is an integrated portion of the main housing structure 203. The circuit board 209 includes any number of ground layers 242 and any number of supply voltage layers 245. The circuit board 209 includes a number of hollow vias 251. The compressible probes 215 extend through the hollow vias 251. A subset of the hollow vias 251 make secure contact with a subset of the compressible probes 215, and provide connections to a ground layer 242 or a supply voltage layer 245 of the circuit board 209.

At step 708, a stiffening plate 212 is attached to the test interconnect assembly 103. The stiffening plate 212 provides rigidity to hold the circuit board 209 solidly in place against the pressure exerted by the compressible robes 215. However, in other cases the circuit board 209 includes a rigid material and/or includes sufficient layers to prevent flexion based on the pressure experienced while retaining the compressible robes 215. Where the circuit board 209 has sufficient strength and rigidity to prevent flexion based on the pressure exerted by the compressible robes 215, the stiffening plate 212 can be omitted. The circuit board 209, the stiffening plate 212, and/or a floating plate can provide a DUT interface of the test interconnect assembly 103. The stiffening plate 212 can include a grid array alignment aid for the grid array of the DUT 106. In some examples, the stiffening plate 212 does not include a grid alignment aid, and a floating plate can provide a suspended grid alignment aid between the stiffening plate 212 and the DUT 106.

At step 710, a load board 109 is connected to the test interconnect assembly 103. The load board 109 can be connected to the cover plate 206 of the test interconnect assembly 103. The test interconnect assembly 103 and the load board 109 can form a portion of the test system 100. The load board 109 can include and/or be connected to a power supply device that provides supply voltages and test patterns. The load board 109 can include circuitry configured to apply positive and/or negative supply voltages and test patterns. The test patterns can include inputting analog and/or digital voltage signals to one or more signal nets, reading analog and/or digital voltage signals from the one or more signal nets, and so on.

At step 712, a DUT 106 is connected to the test interconnect assembly 103. The DUT 106 is inserted or connected to a grid alignment aid of the test interconnect assembly 103. The test interconnect assembly 103 provides the grid alignment aid as part of the stiffening plate 212 or a floating plate. The contacts of the DUT 106 can connect to the compressible probes 215 of the test interconnect assembly 103. The compressible probes 215 provide paths between the contacts of the DUT 106 and corresponding contacts of the load board 109.

In sum, the disclosed techniques include a housing structure that houses at least a portion of one or more compressible probes, a plate on a first surface corresponding to a load-board-side of the housing structure closer to a load board, and a circuit board on a second surface corresponding to a DUT-side of the housing structure closer to the DUT than the load board. The plate retains the compressible probes for connection to the load board. The circuit board includes one or more conductive planes that provide a conductive path for a supply voltage for DUT, and the test interconnect is configured to interface with the DUT closer to the second surface of the housing structure than the first surface of the housing structure.

At least one technical advantage of the disclosed techniques relative to the prior art is that, with the disclosed techniques, a more accurate measurement of power supply voltage is obtained. Another technical advantage is that power supply integrity is increased. The improved power supply integrity reduces the likelihood of cause electrical damage, heat damage, and/or other damage to the DUT, the test socket, and the load board during testing. These technical advantages provide one or more technological advancements over prior art approaches.

Aspects of the subject matter described herein are set out in the following numbered clauses.

1. In some embodiments, a test interconnect comprises a housing structure that houses at least a portion of one or more compressible probes, a plate on a first surface of the housing structure, wherein the plate retains the one or more compressible probes for connection to a load board, and a circuit board on a second surface of the housing structure opposite the first surface, the circuit board comprising one or more conductive planes that provide a conductive path for a supply voltage for a device under test (DUT), wherein the test interconnect is configured to interface with the DUT closer to the second surface of the housing structure than the first surface of the housing structure.

2. The test interconnect of clause 1, further comprising a stiffening plate on a surface of the circuit board opposite the housing structure, wherein the stiffening plate comprises a grid alignment aid for a grid array of the DUT.

3. The test interconnect of clauses 1 or 2, wherein the circuit board comprises one or more grid array vias concentric to a grid array of the DUT, wherein at least a subset of the one or more compressible probes extends through the one or more grid array vias for connection to the device under test.

4. The test interconnect of any of clauses 1-3, wherein the one or more compressible probes comprise a first one or more compressible probes configured to connect to the DUT and the load board, and a second one or more compressible probes configured to connect to one or more voltage measurement contact pads, wherein the one or more voltage measurement contact pads connect to at least one of the one or more conductive planes.

5. The test interconnect of any of clauses 1-4, further comprising a Kelvin-type measurement probe that connects to a supply voltage measurement contact of the circuit board and to at least one of a supply voltage measurement contact of the load board, or a cable connection of a testing device.

6. The test interconnect of any of clauses 1-5, further comprising a floating plate comprising a grid alignment aid for a grid array of the DUT, wherein the floating plate is between the circuit board and the DUT.

7. The test interconnect of any of clauses 1-6, further comprising a probe spacer that holds a compressible probe of the one or more compressible probes concentric with a grid array of the DUT.

8. The test interconnect of any of clauses 1-7, wherein the circuit board and the housing structure are components of a composite construction comprising one or more dielectric materials and one or more conductive layers.

9. The test interconnect of any of clauses 1-8, wherein the circuit board comprises one or more hollow conductive vias, and the one or more compressible probes extend through the one or more hollow conductive vias.

10. The test interconnect of any of clauses 1-9, wherein the housing structure or a conductive sheath within the housing structure is grounded to provide a coaxial transmission path for at least a subset of the one or more compressible probes.

11. In some embodiments, a system comprises a load board comprising one or more load board contacts, a test interconnect assembly located between the load board and a device under test (DUT) interface of the test interconnect assembly, the test interconnect assembly comprising a housing structure that houses at least a portion of one or more compressible probes, a plate on a first surface of the housing structure closer to the load board than the DUT, wherein the plate retains the one or more compressible probes, and a circuit board on a second surface of the housing structure closer to the DUT interface than the load board, the circuit board comprising one or more conductive planes that provide a conductive path for a supply voltage.

12. The system of clause 11, the test interconnect assembly further comprising a stiffening plate on a surface of the circuit board opposite the housing structure, wherein the stiffening plate comprises a grid alignment aid.

13. The system of clauses 11 or 12, wherein the circuit board comprises one or more grid array vias concentric to a grid array of the device under test, and at least a subset of the one or more compressible probes extends through the one or more grid array vias.

14. The system of any of clauses 11-13, further comprising a Kelvin-type measurement probe that connects to a supply voltage measurement contact of the circuit board and to at least one of a supply voltage measurement contact of the load board, or a cable connection of a testing device.

15. In some embodiments, a method comprises providing a test interconnect assembly comprising a device under test (DUT) interface, housing, using a housing structure of the test interconnect assembly, at least a portion of one or more compressible probes, attaching a plate of the test interconnect assembly on a first surface of the housing structure, wherein the plate retains the one or more compressible probes, attaching a circuit board on a second surface of the housing structure, the circuit board comprising one or more conductive planes that provide a conductive path for a supply voltage, and connecting a load board to the plate of the of the test interconnect assembly, the load board comprising load board contacts, wherein the test interconnect assembly is configured to connect to a DUT closer to the circuit board than the load board, the DUT comprising one or more DUT contacts.

16. The method of clause 15, further comprising positioning a Kelvin-type measurement probe within at least one of a DUT footprint of the DUT, or a grid array footprint of the DUT.

17. The method of clauses 15 or 16, wherein the DUT interface comprises a floating plate that includes a grid alignment aid for the DUT.

18. The method of any of clauses 15-17, wherein the DUT interface comprises a stiffening plate that includes a grid alignment aid for the DUT.

19. The method of any of clauses 15-18, further comprising positioning a Kelvin-type measurement probe outside at least one of a DUT footprint of the DUT, or a grid array footprint of the DUT.

20. The method of any of clauses 15-19, further comprising applying one or more supply voltages, performing one or more test patterns, obtaining one or more measurements using a Kelvin-type measurement probe of the one or more compressible probes, and performing one or more power management actions based on the one or more measurements.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments can be embodied as a system, method or computer program product. Accordingly, aspects of the present disclosure can take the form of an entirely hardware embodiment, an entirely software embodiment (including firmware, resident software, micro-code, etc.) or an embodiment combining software and hardware aspects that can all generally be referred to herein as a “module,” a “system,” or a “computer.” In addition, any hardware and/or software technique, process, function, component, engine, module, or system described in the present disclosure can be implemented as a circuit or set of circuits. Furthermore, aspects of the present disclosure can take the form of a computer program product embodied in one or more computer readable medium(s) having computer readable program code embodied thereon.

Any combination of one or more computer readable medium(s) can be utilized. The computer readable medium can be a computer readable signal medium or a computer readable storage medium. A computer readable storage medium can be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium can be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions can be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors can be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams can represent a module, segment, or portion of code, which comprises one or more executable instructions for implementing the specified logical function(s). It should also be noted that, in some alternative implementations, the functions noted in the block can occur out of the order noted in the figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure can be devised without departing from the basic scope thereof, and the scope thereof is determined by the claims that follow.

What is claimed is:

1. A test interconnect comprising:
a housing structure that houses at least a portion of one or more compressible probes;
a plate on a first surface of the housing structure, wherein the plate retains the one or more compressible probes for connection to a load board; and
a circuit board on a second surface of the housing structure opposite the first surface, the circuit board comprising one or more conductive planes that provide a conductive path for a supply voltage for a device under test (DUT), wherein the test interconnect is configured to interface with the DUT closer to the second surface of the housing structure than the first surface of the housing structure.

2. The test interconnect of claim 1, further comprising:
a stiffening plate on a surface of the circuit board opposite the housing structure, wherein the stiffening plate comprises a grid alignment aid for a grid array of the DUT.

3. The test interconnect of claim 1, wherein the circuit board comprises:
one or more grid array vias concentric to a grid array of the DUT, wherein at least a subset of the one or more compressible probes extends through the one or more grid array vias for connection to the device under test.

4. The test interconnect of claim 1, wherein the one or more compressible probes comprise:
a first one or more compressible probes configured to connect to the DUT and the load board; and
a second one or more compressible probes configured to connect to one or more voltage measurement contact pads, wherein the one or more voltage measurement contact pads connect to at least one of the one or more conductive planes.

5. The test interconnect of claim 1, further comprising:
a Kelvin-type measurement probe that connects to a supply voltage measurement contact of the circuit board and to at least one of: a supply voltage measurement contact of the load board, or a cable connection of a testing device.

6. The test interconnect of claim 1, further comprising:
a floating plate comprising a grid alignment aid for a grid array of the DUT, wherein the floating plate is between the circuit board and the DUT.

7. The test interconnect of claim 1, further comprising:
a probe spacer that holds a compressible probe of the one or more compressible probes concentric with a grid array of the DUT.

8. The test interconnect of claim 1, wherein the circuit board and the housing structure are components of a composite construction comprising one or more dielectric materials and one or more conductive layers.

9. The test interconnect of claim 1, wherein the circuit board comprises one or more hollow conductive vias, and the one or more compressible probes extend through the one or more hollow conductive vias.

10. The test interconnect of claim 1, wherein the housing structure or a conductive sheath within the housing structure is grounded to provide a coaxial transmission path for at least a subset of the one or more compressible probes.

11. A system comprising:
a load board comprising one or more load board contacts;
a test interconnect assembly located between the load board and a device under test (DUT) interface of the test interconnect assembly, the test interconnect assembly comprising:
a housing structure that houses at least a portion of one or more compressible probes;
a plate on a first surface of the housing structure closer to the load board than the DUT, wherein the plate retains the one or more compressible probes; and
a circuit board on a second surface of the housing structure closer to the DUT interface than the load board, the circuit board comprising one or more conductive planes that provide a conductive path for a supply voltage.

12. The system of claim 11, the test interconnect assembly further comprising:
a stiffening plate on a surface of the circuit board opposite the housing structure, wherein the stiffening plate comprises a grid alignment aid.

13. The system of claim 11, wherein the circuit board comprises:
one or more grid array vias concentric to a grid array of the device under test, and at least a subset of the one or more compressible probes extends through the one or more grid array vias.

14. The system of claim 11, further comprising:
a Kelvin-type measurement probe that connects to a supply voltage measurement contact of the circuit board and to at least one of: a supply voltage measurement contact of the load board, or a cable connection of a testing device.

15. A method comprising:
providing a test interconnect assembly comprising a device under test (DUT) interface;
housing, using a housing structure of the test interconnect assembly, at least a portion of one or more compressible probes;
attaching a plate of the test interconnect assembly on a first surface of the housing structure, wherein the plate retains the one or more compressible probes;
attaching a circuit board on a second surface of the housing structure, the circuit board comprising one or more conductive planes that provide a conductive path for a supply voltage; and
connecting a load board to the plate of the of the test interconnect assembly, the load board comprising load board contacts;
wherein the test interconnect assembly is configured to connect to a DUT closer to the circuit board than the load board, the DUT comprising one or more DUT contacts.

16. The method of claim 15, further comprising:
positioning a Kelvin-type measurement probe within at least one of: a DUT footprint of the DUT, or a grid array footprint of the DUT.

17. The method of claim 15, wherein the DUT interface comprises a floating plate that includes a grid alignment aid for the DUT.

18. The method of claim 15, wherein the DUT interface comprises a stiffening plate that includes a grid alignment aid for the DUT.

19. The method of claim 15, further comprising:
positioning a Kelvin-type measurement probe outside at least one of: a DUT footprint of the DUT, or a grid array footprint of the DUT.

20. The method of claim 15, further comprising:
applying one or more supply voltages;
performing one or more test patterns;
obtaining one or more measurements using a Kelvin-type measurement probe of the one or more compressible probes; and
performing one or more power management actions based on the one or more measurements.
